(19) United States
(12) Patent Application Publication
(10) Pub. No.: US 2007/0140015 A1
(43) Pub. Date: Jun. 21, 2007

(54) Nonvolatile semiconductor memory device

(75) Inventor: Shoichi Kawamura, Yokohama (JP)

Correspondence Address: F. Chau & Associates, LLC, 130 Woodbury Road, Woodbury, NY, 11797, US

(73) Assignee: Samsung Electronics Co., Ltd.

(21) Appl. No.: 11/639,807

(22) Filed: Dec. 16, 2006

(30) Foreign Application Priority Data
Dec. 20, 2005 (JP) 2005-367261

(51) Int. Cl. G11C 11/34

(52) U.S. Cl. 365/185.22

(57) ABSTRACT

A nonvolatile semiconductor memory device. The nonvolatile semiconductor memory device includes a memory cell formed in a first well outputs a first voltage in response to a reference voltage necessary for program and erase verify operations. A reference cell formed in a second well generates a second voltage in response to the reference voltage in the program and erase verify operations. A comparator circuit compares the first voltage to the second voltage to detect whether the verify operation for the memory cell has passed, in the verify operation. A bias applying unit applies the same bias voltage to the first and second wells in the verify operation: Although there is an over-erased cell, an erase verify, operation can be correctly performed.

### CROSS-REFERENCE TO RELATED APPLICATIONS

This application claims priority under 35 U.S.C. § 119 to Japanese Patent Application No. 2005-367261, filed on Dec. 20, 2005, the entire contents of which are hereby incorporated by reference.

### BACKGROUND OF THE INVENTION

### Technical Field

The present disclosure relates to a memory device, and more particularly, to a nonvolatile semiconductor memory device.

FIGS. 5A and SB illustrate a circuit of a NOR type electrically erasable and programmable ROM (EEPROM). FIG. 5A is a circuit diagram of the conventional NOR type EEPROM, and FIG. 5B is a cross-sectional view of a section surrounded by the dotted line of FIG. 5A.

In the NOR type EEPROM, memory cell transistors M1, M2, . . . , M6 each include sources connected in parallel with a common source line SL and drains connected in parallel with a bit line BL2. Word lines WL1, WL2, . . . , WL6 are connected with gates of the memory cell transistors Ml, M2, . . . , M6 to form NOR arrays. Other NOR arrays are disposed adjacent to the NOR arrays. The NOR arrays are formed in a P-well 300 in a substrate 100 to comprise a memory cell array. Generally, a well is formed of a duplex well. For example, N-type impurities are implanted into a P-type semiconductor substrate 100 to form an N-well 200, and P-type impurities are implanted into a portion of the N-well 200 to form the P-well 300. N-type memory cell transistors are formed in the P-well 300.

Control gates CG1, CG2, . . . , CG6 of the memory cell transistors M1, M2, . . . , M6 are connected with the word lines WL1, WL2, . . . , WL6, respectively. A program operation is performed by injecting electrons into floating gates FG1, FG2, . . . , FG6 of the memory cell transistors M1, M2, . . . , M6, and an erase operation is performed by removing the implanted electrons from the floating gates FG1, FG2, . . . , FG6.

Generally, in a program operation, a high voltage is applied to a word line WL and a bit line BL of the selected cell, a common source line SL is maintained at approximately a ground potential, the substrate 100 or the P-well 300 is maintained at a ground level, and hot electrons are injected into a floating gate FG around a drain of a memory cell transistor M. This is called a channel hot electron injection (CHEI).

In an erase operation, the word line WL is biased to a ground potential or a negative voltage. The bit line BL is floated. The substrate 100 or the P-well 300 is grounded. A high voltage is applied to the common source line SL to remove electrons from the floating gate FG to the source. This is called a diffusion layer FN-tunneling. Alternatively, a ground voltage or a negative voltage is applied to the word line WL. The bit line BL and the common-source line SL are floated. A high voltage is applied to the P-well 300 to remove electrons from the floating gate FG to the substrate 100. Elis is called a substrate FN-tunneling.

A threshold voltage (Vt) of the memory cell transistor increases after a program operation. When an erase operation is performed, the threshold voltage Vt decreases.

FIG. 6 is a distribution view of a threshold voltage Vt of the programmed cell or the erased cell after a program or erase operation is performed. Generally, a program operation is performed on a byte or word basis. An erase operation is performed overall for all memory cell transistors.

Whether an erase operation has been completely performed is checked using erase verify. In the erase verify, a reference voltage V_{R} higher than a threshold voltage Vₜₑ of an erased cell is applied to a word line WL of a cell transistor to be verified, as illustrated in FIG. 6. A ground potential is applied to a word line of another cell transistor. Here, when the cell transistor is turned on, it is judged that erase has been completed. When the cell transistor is not turned on, it is judged that erase has not been completed and an erase should be perfumed again.

Since memory cells are arranged in parallel in a NOR type EEPROM, as illustrated in FIG. 5, a cell may be over-erased. The over erase means that an erase operation is excessively performed, and thus a threshold voltage Vt of an erased cell decreases below a proper range. FIG. 7 is a distribution view of a threshold voltage of an over-erased cell after erase verify.

FIG. 8 is view illustrating a problem caused due to an over-erased memory cell in a NOR type EEPROM. Referring to FIG. 8, a memory cell 10 is selected, and an erase verify operation is performed on the memory cell 10. A reference voltage V_{R} is applied to a word line WL1 connected with a control gate of the memory cell 10 and a ground potential is applied to a word line WL2 of an unselected memory cell 20. Here, when the memory cell 20 is a properly erased cell, the memory cell 20 is in an “off” state. Therefore, a current does not flow from a bit line BL to a common source line SL through the memory cell. Also when the selected memory cell 10 is a completely erased cell the memory cell 10 achieves an “on” state. Here, when a current Ie flowing through the memory cell 10 from the bit line BL is within a permissible range, it is judged that erase verify has failed. On the other hand, when the current Ie is not within a permissible range, it is judged that the erase verify has passed.

When the memory cell 20 is an over erased cell the memory cell 20 is not completely in an “off” state and a leakage current Il flows through the memory cell 20 from the bit line BL. The leakage current Il is detected with the current Ie flowing through the memory cell 10. Therefore, the memory cell 10 is under-erased and the current Ie flowing through the memory cell 10 decreases. Thus, it may be judged that the erase verify is “pass,” not “fail.”

Soft programs may then be preformed after an erase operation to compensate for the over erase.

Although erase verify is judged to have passed due to the leakage current Il flowing through the over-erased memory cell 20, the over erase of the memory cell 20 is solved using the soft program. However, since a threshold voltage of the under-erased memory cell 10 returns to an original threshold voltage Vt higher than a reference voltage, a margin failure may occur when a read operation is performed after an erase operation.

FIG. 9 illustrates change in a threshold voltage Vt of an erased cell after an erase verify operation is performed and after a soft program is performed, respectively. Referring to FIG. 9, a distribution of a threshold voltage Vt of an erased cell ERS Vt distribution enlarges due to the under-erased memory cell after performing a soft program.

In order to perform an erase verify operation without being affected by a leakage current due to an over-erased memory cell, the over-erased memory cell should not create a leakage current. In this regard, a negative voltage may be applied to a P-well where a memory cell is formed to provide a back bias to the memory cell and increase a threshold voltage Vt of the memory cell. When the over-erased memory cell is not selected, the unselected memory cell may be set to an “off” state such that a leakage current is not created.

However, in the above-mentioned method, a threshold voltage of the memory cell selected to perform an erase verify operation increases due to a back bias effect. Therefore, a reference voltage V_{R} is not applied to perform an erase verify operation.

FIG. 10 is a view illustrating a relation between a word line voltage Vwl and a current flowing through an over-erased cell and a selected cell respectively when a negative voltage bias is applied. Referring to FIG. 10, a leakage current of an over-erased cell is removed due to a negative voltage bias. A threshold voltage of a selected cell increases. Therefore, when the same voltage level EV level is applied to a word line, a read current decreases, and thus an erase verify operation is not performed.

A program verify method is discussed in Japanese Laid-open Patent Publication No. 2001-127176, a reference voltage defining a lower limit and an upper limit of a programmed cell is used in the program verify method. Japanese Laid-open Patent Publication No. 2004-185688 relates to an erase verify method for a NAND flash memory, and more particularly, to a method of exactly verifying a threshold voltage (Vt) of an erased cell without being affected by a back bias. Japanese Laid-open Patent Publication No. 2004-348802 relates to a method of improving a drive performance of an EEPROM by controlling a threshold voltage (Vt) of an erased cell and applying a back bias in a read operation.

### SUMMARY OF THE INVENTION

The present disclosure provides a nonvolatile semiconductor memory device in which an influence of a leakage current of an over-erased cell can be removed to perform an erase verify operation.

Exemplary embodiments of the present invention provide nonvolatile semiconductor memory devices. A memory cell is formed in a first well and outputs a first voltage in response to a reference voltage for program and erase verify operations. A reference cell is formed in a second well and generates a second voltage in response to the reference voltage in the program and erase verify operations. A comparator circuit compares the first voltage to the second voltage to detect whether the verify operation for the memory cell has passed in the verify operation. A bias applying unit applies the same bias voltage to the first and second wells in the verify operation.

In some exemplary embodiments, the bias applying unit includes a negative voltage generating circuit for generating a negative voltage. A negative voltage bias circuit is additionally included for adjusting the negative voltage to a predetermined voltage level. This supplies the adjusted voltage as the bias voltage in response a timing signal of the verify operation.

In other exemplary embodiments, the bias voltage is −1 V.

In still other exemplary embodiments, the memory cell is a NOR type memory cell.

In other exemplary embodiments of the present invention, a nonvolatile semiconductor memory device includes a memory cell formed in a first well to output a first read current in response to a reference voltage provided in program and erase verify operations. The memory cell includes a semiconductor device capable of electrically programming and erasing data A reference cell is formed in a second well to output a second read current in response to the reference voltage in the program and erase verify operations. A comparator circuit compares the first read current to the second read current to detect whether the verify operation for the memory cell has passed in the program and erase verify operations. A bias applying unit applies the same bias voltage to the first and second wells in the program and erase verify operation.

In some exemplary embodiments, the bias applying unit includes a negative voltage generating circuit for generating a negative voltage. A negative voltage bias circuit is additionally included for adjusting the negative voltage to a predetermined voltage level to supply the adjusted voltage as the bias voltage in response a timing signal of the verify operation.

In other exemplary embodiments, the bias voltage is −1 V.

In still other exemplary embodiments, the memory cell is a NOR type memory cell.

### BRIEF DESCRIPTION OF THE DRAWINGS

The accompanying figures are included to provide a further understanding of the present disclosure, and are incorporated in and constitute a part of this specification. The drawings illustrate exemplary embodiments of the present invention and, together with the description, serve to explain principles of the present disclosure. In the figures:

FIG. 1 is a block diagram of a nonvolatile semiconductor memory device according to an exemplary embodiment of the present invention.

FIG. 2 is a graph illustrating a relation between a word line voltage and a current flowing through a memory cell when a back bias is applied to the memos cell;

FIG. 3 is a circuit diagram of a voltage bias circuit according to an exemplary embodiment of present invention;

FIG. 4 is a timing waveform diagram illustrating an operation of each part illustrated in FIG. 3;

FIG. 5A is a circuit diagram of a NOR type EEPROM;

FIG. 5B is a cross-sectional view of a NOR type EEPROM;

FIG. 6 is a distribution view of a threshold voltage of each cell after a program or erase operation;

FIG. 7 is a distribution view of a threshold voltage of an erased cell when there is an over-erased cell;

FIG. 8 is view illustrating a problem of the case where there is an over-erased memos cell in erase verify for a NOR type EEPROM;

FIG. 9 is a view illustrating changes in threshold voltages after erase verify and after program return of a soft program is performed, respectively; and

FIG. 10 is a view illustrating a relation between a word line voltage and a current flowing through a cell in an over-erased cell and a selected cell respectively when a negative voltage bias is applied.

### DETAILED DESCRIPTION OF EXEMPLARY EMBODIMENTS

An exemplary embodiment of the present invention is described below in conjunction with the accompanying drawings.

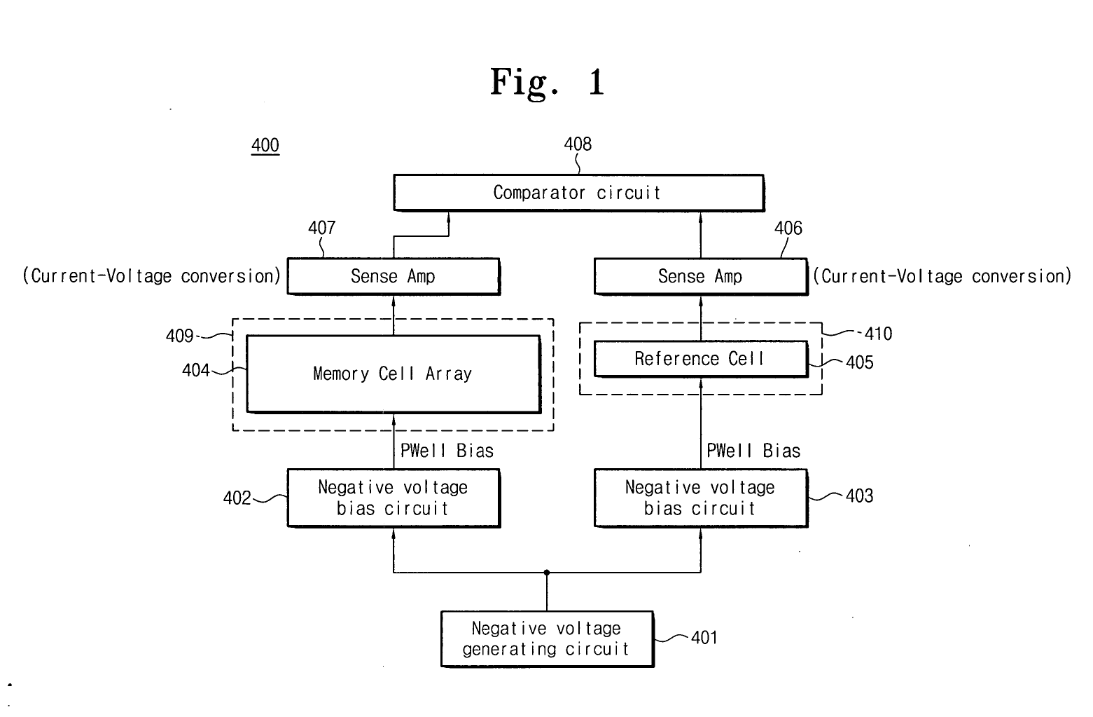

FIG. 1 is a block diagram of a nonvolatile semiconductor memory device 400 according to an exemplary embodiment of the present invention. Referring to FIG. 1, in the nonvolatile semiconductor memory device 400, a memory cell array 404 including a plurality of semiconductor devices that can electrically program and erase information is formed in a P-well 409 formed in a semiconductor substrate. Similarly, a reference cell 405 generating a reference voltage for program and erase verify for a memory cell is formed in a P-well 410 formed in the semiconductor substrate.

The nonvolatile semiconductor memory device 400 includes a negative voltage generating circuit 401 to generate a negative voltage, for example, −1 V.

Negative voltage bias circuits 402 and 403 receive an output from the negative voltage generating circuit 401 to generate a predetermined negative voltage (for example. −1 V) as a back bias voltage. In a verify operation, an output of the negative voltage bias circuit 402 is applied to the P-well 409 and an output of the negative voltage bias circuit 403 is applied to the P-well 410. Outputs of the negative voltage bias circuits 402 and 403 are not applied to the P-wells 409 and 410 in a usual operation state without verifying. The negative voltage bias circuits 402 and 403 may be driven in response to an erase verify signal for such a control. When the erase verify signal is input, the negative voltage bias circuits 402 and 403 output a negative voltage (for example. −1 V). When the negative voltage bias circuits 402 and 403 are not driven, the negative voltage bias circuits 402 and 403 output 0 V.

A sense amp 407 performs current-voltage conversion on an output of the memory cell array 404. The output of the sense amp 407 is then transferred to a comparator circuit 408. Another sense amp 406 performs current-voltage conversion on an output of the reference cell 405. The output of the other sense amp 406 is transferred to the comparator circuit 408 as a comparator voltage. In an erase verify operation, a reference voltage applied to the reference cell 405 is applied to each memory cell of the memory cell array 404 to read information stored in the memory cell, and the information is transferred to the comparator circuit 408.

Next, the comparator circuit 408 performs an erase verify operation by comparing the information to the comparator voltage received from the reference cell 405. An example of an erase verily method is discussed in Japanese Laid-open Patent Publication No. 2001-127176.

The same bias voltage is applied to the P-well 409 where the memory cell array 404 is formed and the P-well 410 where the reference cell 405 is formed in the erase verify operation. The bias voltage of −1 V is used in the present exemplary embodiment, but the bias voltage is not limited thereto. An optimized bias voltage may be selected to prevent a leakage current of an erased cell.

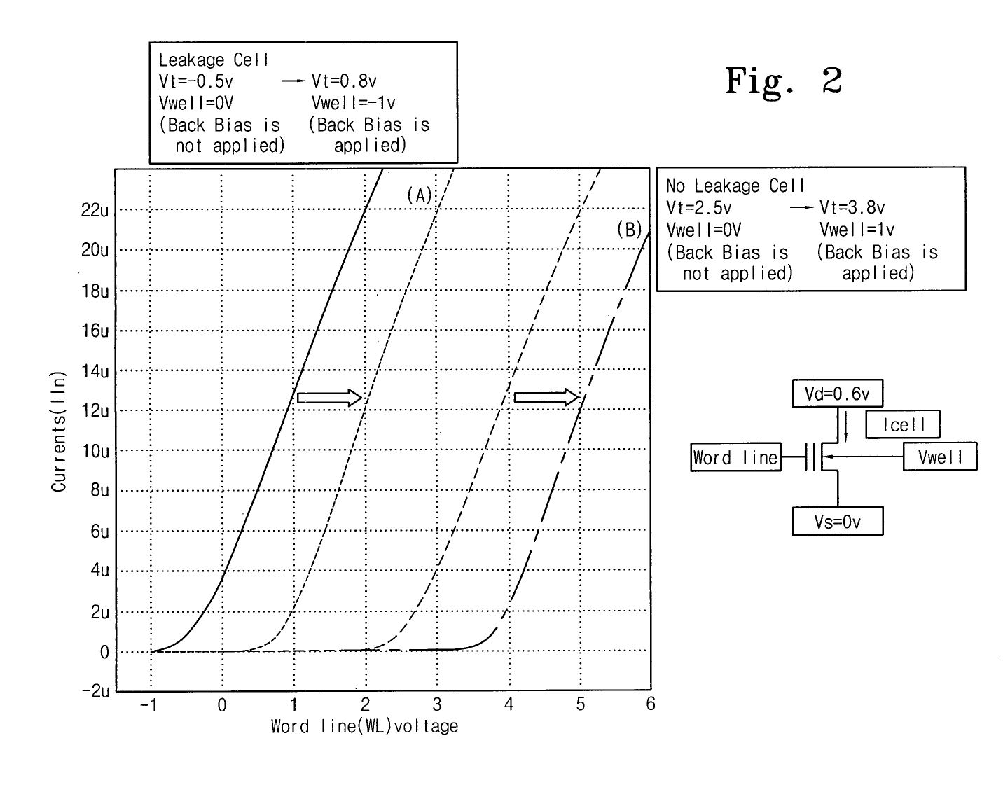

FIG. 2 is a graph illustrating a relation between a word line voltage and a sense current when a back bias is applied to the memory cell according to the exemplary embodiment shown in FIG. 1. FIG. 2 illustrates a relation between a word line voltage and a current flowing through a cell when a drain voltage of 0.6 V, a source voltage of 0 V. and a back bias voltage of −1 V are applied to a semiconductor device constituting a cell.

A curve (A) illustrates a cell where a leakage current is generated in an erase verify operation due to over erase, and a curve (B) illustrates a cell where a leakage current is not generated. In the cell where a leakage current is generated, a threshold voltage (Vt) is −0.5 V when a bias voltage is not applied, and increases to 0.8 V when a bias voltage is applied.

In the cell where a leakage current is not generated, a threshold voltage (Vt) is 2.5 V when a bias voltage is not applied, and increases to 3.8 V when a bias voltage is applied. In either case, a change value is equal 1.3 V. For example, a change value of a threshold voltage due to application of a back bias voltage is same in both an over-erased memory cell and a non-erased memory cell.

Therefore, the relationship between a memory cell and a reference cell is the same as the case where an erase verify operation is performed when a back bias voltage is not applied. FIG. 2 shows that although there is an over-erased cell, an erase verify operation may be performed using a desirable reference voltage.

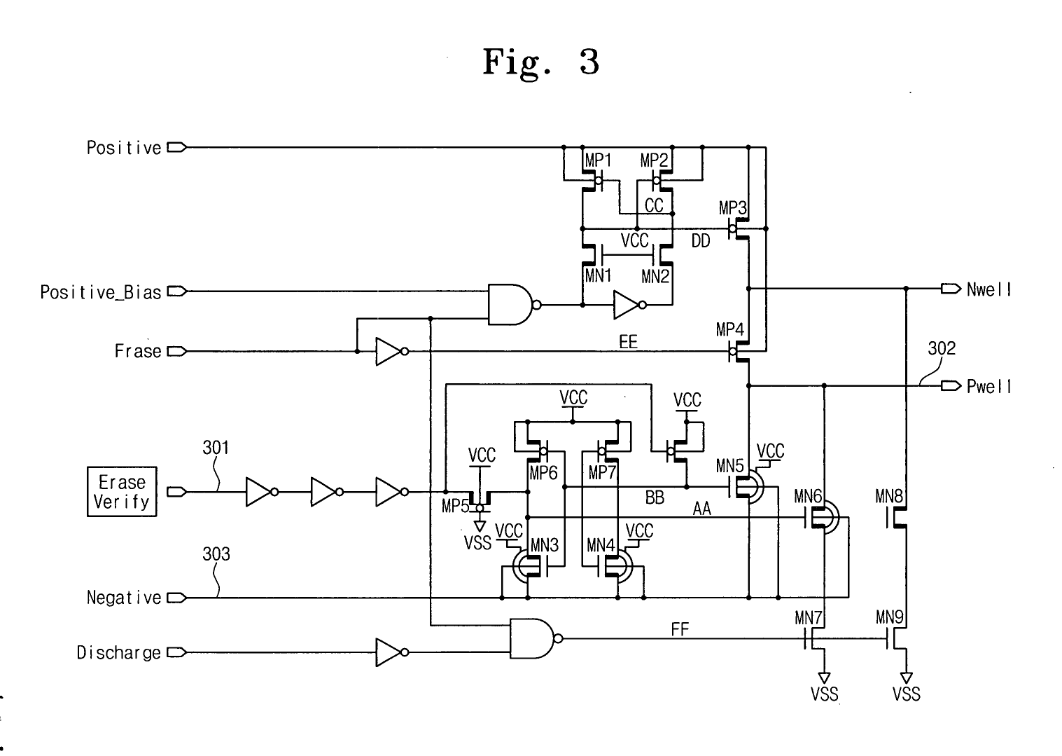

FIG. 3 is an exemplary circuit diagram illustrating the negative voltage bias circuits 402 and 403 illustrated in FIG. 1.

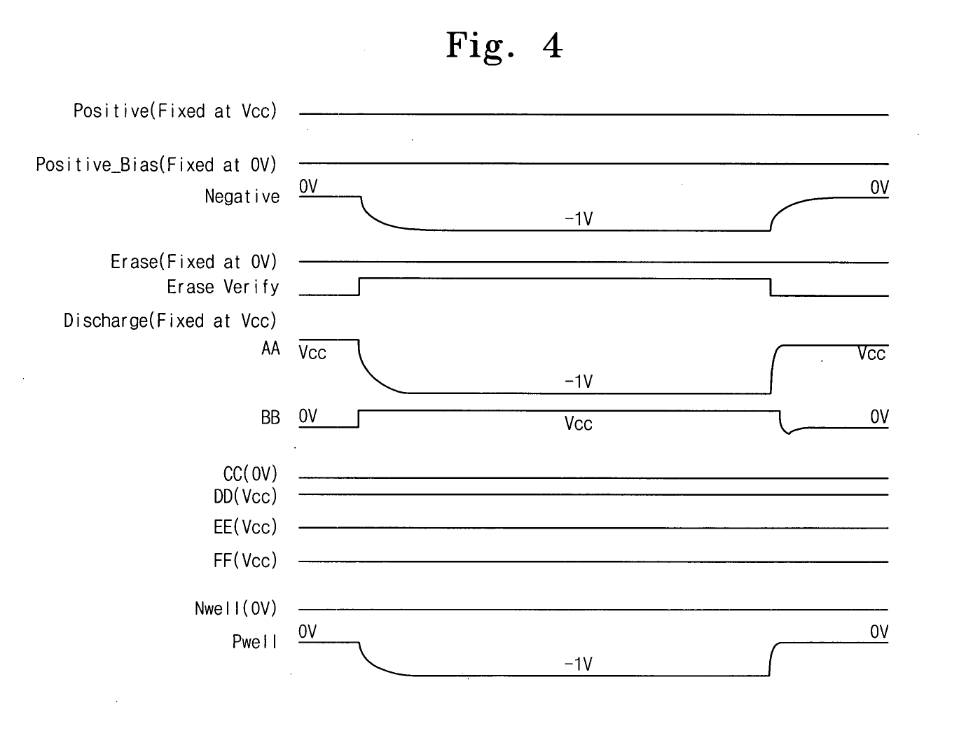

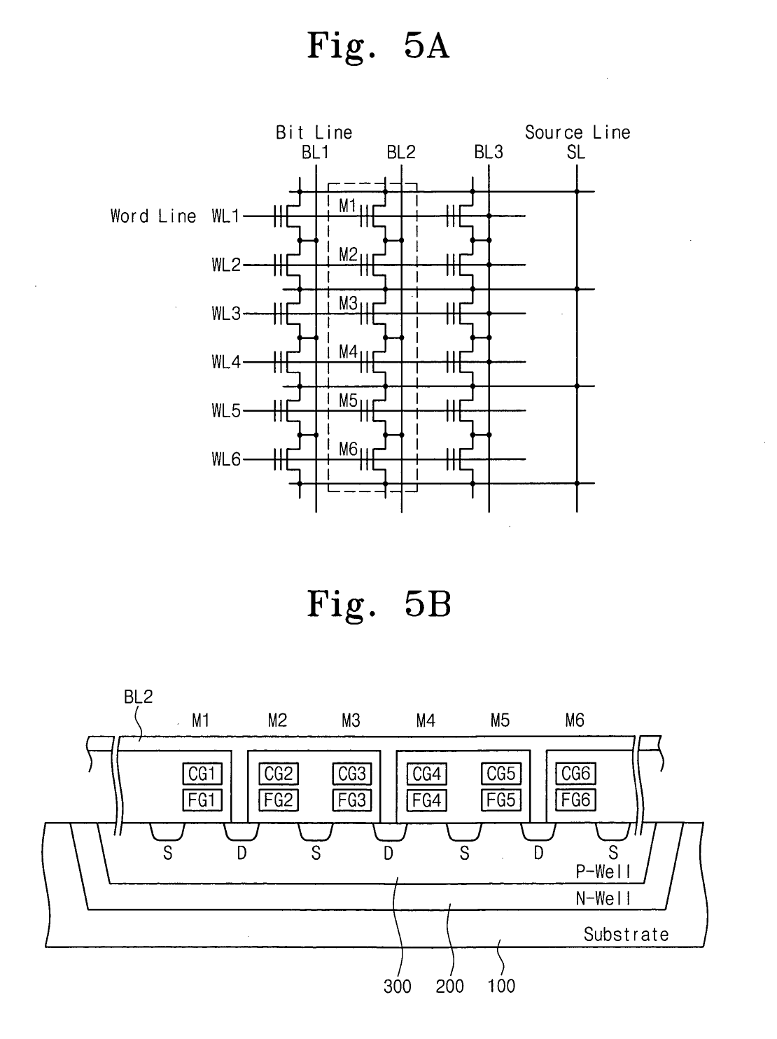

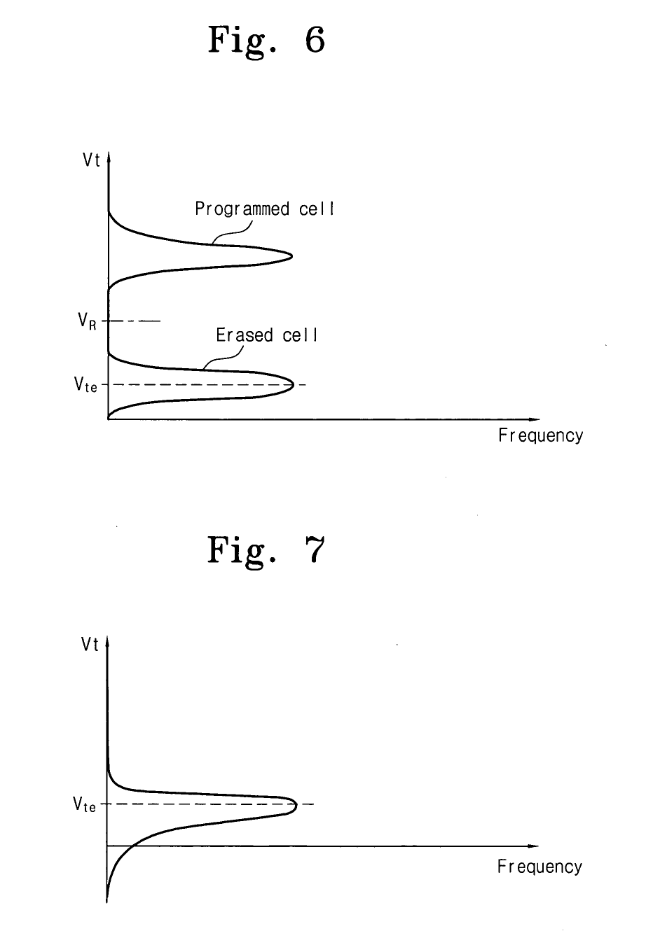

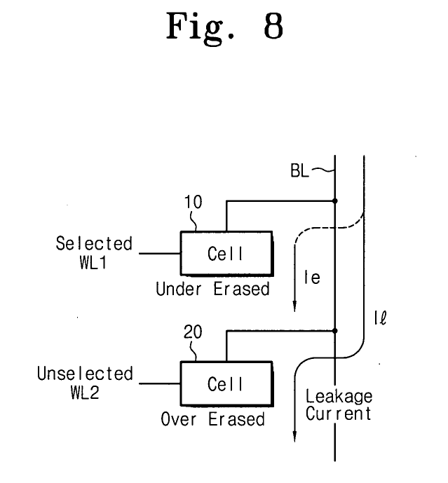

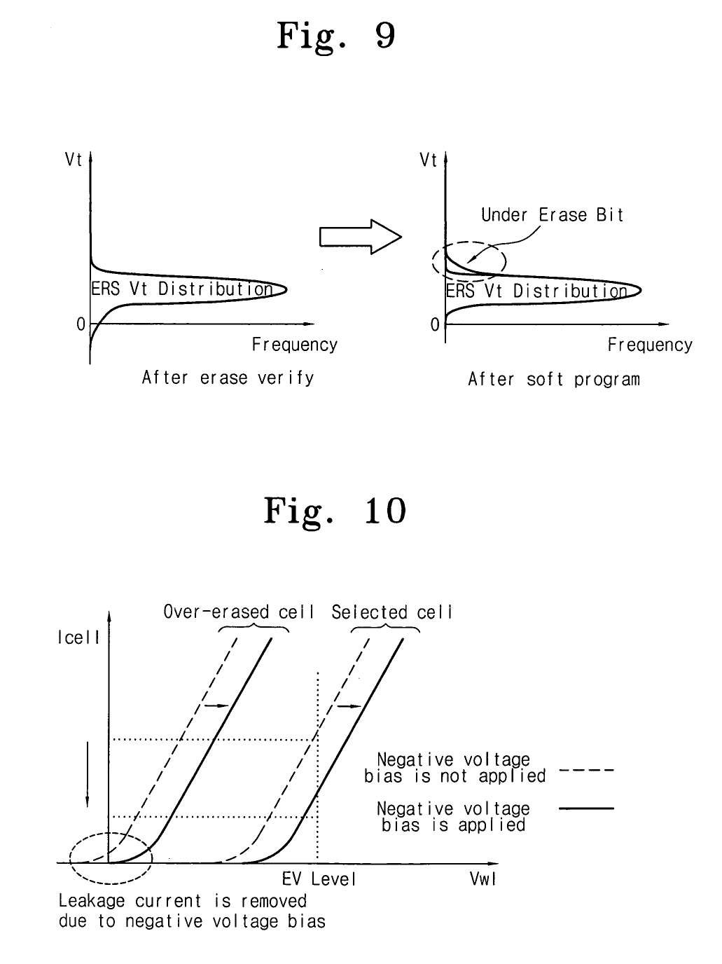

FIG. 4 is a timing waveform diagram illustrating an operation of each part of a circuit illustrated in FIG. 3.

In the circuit of FIG. 3, when an erase verify signal is applied to a terminal 301, a bias voltage of −1 V is generated in a terminal 302. The generated bias voltage is applied to the P-well 409 formed in the memory cell array 404 and the P-well 410 formed in the reference cell 405.

A voltage bias circuit of FIG. 3 is in accordance with an exemplary embodiment of the present invention and it will be understood that various changes may be made therein.

The negative voltage bias circuits 402 and 403 are separately provided in the exemplary embodiment illustrated in FIG. 1, but the same bias voltage may be simultaneously supplied from one voltage bias circuit to the both P-wells.

A negative voltage is supplied from a negative voltage generating circuit (not shown) to the negative voltage bias circuit of FIG. 3. A negative voltage of −1 V is applied to a negative voltage supply terminal 303 and the same bias voltage is output through the terminal 302. However, a negative voltage generated from the negative voltage generating circuit may be supplied as a bias voltage by adjusting a voltage level.

A predetermined bias voltage may be selected in response to a leakage current in an erase verify due to over-erase, but a bias voltage of approximately −1 V may be generally selected.

A NOR type memory is illustrated as an example of a nonvolatile semiconductor device in the present exemplary embodiment, but the present disclosure may be applied to a memory of other cell types.

According to an exemplary embodiment of the present invention, since the same back bias voltage is applied to a memory cell and a reference cell in a verify operation, a relationship between the memory cell and die reference cell is same as the relationship in the case of erase verify when the back bias voltage is not applied. Therefore, although there is an over-erased cell, an erase verify operation can be performed without an effect of the over-erased cell.

As a result, under-erased cells may be minimized or entirely avoided. The effects of over-erased cells man be minimized or avoided by the performance of a soft program.

The above disclosure is to be considered illustrative, and not restrictive.

What is claimed is:

1. A nonvolatile semiconductor memory device, comprising:
a memory cell formed in a first well to output a first voltage in response to a reference voltage in a program operation and an erase verify operation;
a reference cell formed in a second well to generate a second voltage in response to the reference voltage in the program operation and the erase verify operation;
a comparator circuit comparing the first voltage to the second voltage to detect whether the verify operation has passed; and
a bias applying unit for applying a bias voltage to the first and second wells in the erase verify operation.

2. The nonvolatile semiconductor memory device of claim 1, wherein the bias applying unit comprises:
a negative voltage generating circuit for generating a negative voltage; and
a negative voltage bias circuit for adjusting the negative voltage to a predetermined voltage level to supply the adjusted voltage as the bias voltage in response a timing signal of the erase verify operation.

3. The nonvolatile semiconductor memory device of claim 1, wherein the bias voltage is −1 V.

4. The nonvolatile semiconductor memory device of claim 1, wherein the memory cell is a NOR type memory cell.

5. A nonvolatile semiconductor memory device, comprising:
a memory cell formed in a first well to output a first read current in response to a reference voltage provided in a program operation and an erase verify operation, the memory cell comprises a semiconductor device capable of electrically programming and erasing data;
a reference cell formed in a second well to output a second read current in response to the reference voltage in the program operation and the erase verify operation:
a comparator circuit comparing the first read current to the second read current to detect whether the verify operation has passed; and
a bias applying unit for applying a bias voltage to the first and second wells in the program operation and the erase verify operation.

6. The nonvolatile semiconductor memory device of claim 5, wherein the bias applying unit comprises:
a negative voltage generating circuit for generating a negative voltage; and
a negative voltage bias circuit for adjusting the negative voltage to a predetermined voltage level to supply the adjusted voltage as the bias voltage in response a timing signal of the erase verify operation.

7. The nonvolatile semiconductor memory device of claim 5, wherein the bias voltage is −1 V.

8. The nonvolatile semiconductor memory device of claim 5, wherein the memory cell is a NOR type memory cell.

9. A method for performing an erase verify operation in a nonvolatile semiconductor memory device, comprising:
outputting a first voltage from a memory cell formed in a first well in response to a reference voltage in a program operation and an erase verify operation;
generating a second voltage in a reference cell in response to the reference voltage in the program operation and the erase verify operation;
comparing the first voltage to the second voltage to detect whether the verify operation has passed; and
applying a bias voltage to the first and second wells in the erase verify operation.

10. The method of claim 9, wherein the bias applying unit comprises:
a negative voltage generating circuit for generating a negative voltage; and
a negative voltage bias circuit for adjusting the negative voltage to a predetermined voltage level to supply the adjusted voltage as the bias voltage in response a timing signal of the erase verify operation.

11. The method of claim 9, wherein the bias voltage is −1 V.

12. The method claim 9, wherein the memory cell is a NOR type memory cell.
